(19) United States
(12) Patent Application Publication
(10) Pub. No.: US 2013/0344689 A1
(43) Pub. Date: Dec. 26, 2013

(54) METHOD FOR PROCESSING SUBSTRATE, METHOD FOR MANUFACTURING SEMICONDUCTOR DEVICE, AND SUBSTRATE PROCESSING APPARATUS

(71) Applicant: Hitachi Kokusai Electric, Inc., Tokyo (JP)

(72) Inventors: Atsushi MORIYA, Toyama-shi (JP); Kiyohisa ISHIBASHI, Toyama-shi (JP); Tatsuya TOMINARI, Toyama-shi (JP)

(73) Assignee: Hitachi Kokusai Electric, Inc., Tokyo (JP)

(21) Appl. No.: 13/915,054

(22) Filed: Jun. 11, 2013

(30) Foreign Application Priority Data
Jun. 11, 2012 (JP) 2012-131857

(51) Int. Cl. H01L 21/02

(52) U.S. Cl. CPC H01L 21/02667
USPC 438/486; 118/712

(57) ABSTRACT

A method for processing a substrate having an insulating film in at least a portion of a surface thereof, a source portion, a drain portion, and a gate portion thereon, and a monocrystalline silicon-based structure in a gate channel disposed under the gate portion. The method for processing a substrate includes: growing amorphous doped silicon and monocrystalline doped silicon by supplying at least silicon-containing gas and doping gas; and monocrystallizing the amorphous doped silicon by using the monocrystalline doped silicon as a seed by heating the amorphous doped silicon and the monocrystalline doped silicon.

### BACKGROUND

1. Technical Field

The present invention relates to a substrate processing apparatus, a method for manufacturing a semiconductor device, and a method for processing a substrate in solid phase epitaxial growth.

2. Related Art

In the implementation of high performance semiconductor devices, device miniaturization approaches the physical limit, and a strained Si technology is expected as one of the new technologies for achieving performance improvement. In the strained Si technology, when a Si crystal lattice is distorted by the application of any one of a compressive stress and a tensile stress to a channel region of a metal oxide semiconductor field effect transistor (MOSFET), the symmetry of an isotropic Si crystal band structure is broken, a split in energy levels occurs, and a band structure is changed. Therefore, carrier scattering is reduced by lattice vibration and effective mass is reduced, resulting in an improvement in the mobility of holes and electrons.

As a method of applying a distortion to a channel region, there is known a method of epitaxially growing a SiGe film, in which Ge having a larger lattice constant than Si is added, in a source/drain portion and indirectly applying a compressive stress to a channel portion, or a method of epitaxially growing a SiC film, in which C having a smaller lattice constant than Si is added, and applying a tensile stress (for example, Japanese Patent Application Laid-Open No. 2006-13106).

Since the mobility of holes is improved by the application of a compressive stress, SiGe is applied to p channel MOSFET (pMOS). Since the mobility of electrons is improved by the application of a tensile stress, SiC is applied to n channel MOSFET (nMOS).

In the nMOS that improves the mobility of electrons by a tensile stress, when SiC is epitaxially grown in a source/drain portion, it is common that P is doped as an n-type dopant.

However, in a chemical vapor deposition (CVD) apparatus, it is known that in Si epitaxial growth in which Si-containing gas such as SiH₄ and P-containing gas such as PH₃ are flowed simultaneously and P is doped in-situ, the growth rate is significantly reduced when a P concentration is increased, that is, when the partial pressure of the P-containing gas is increased (for example, FIG. 2(a) of Surf. Interface Anal., 34 (2002)423). This is because a deposition rate (DR) is slowed down since a wafer surface is covered with P at a high PH₃ partial pressure and a Si dangling bond (covalent bond coordination number) is blocked, for example. Therefore, since the P concentration cannot be increased to a desired concentration, the SiC film cannot be epitaxially grown, or the productivity is significantly degraded when the P concentration is increased.

### SUMMARY

The present invention has been made in consideration of such actual circumstances, and provides a method for processing a substrate, a method for manufacturing a semiconductor device, and a substrate processing apparatus, which can form a source/drain region with a desired dopant concentration while ensuring a deposition rate.

According to an aspect of the present invention, there is provided a method for processing a substrate having an insulating film in at least a portion of a surface thereof, a source portion, a drain portion, and a gate portion, the method for processing a substrate including: growing monocrystalline doped silicon in a gate channel provided under the gate portion, and also growing amorphous doped silicon, by supplying at least silicon-containing gas and doping gas; and monocrystallizing the amorphous doped silicon by using the monocrystalline doped silicon as a seed by heating the amorphous doped silicon and the monocrystalline doped silicon.

Also, according to another aspect of the present invention, there is provided a method for manufacturing a semiconductor device by processing a substrate having an insulating film in at least a portion of a surface thereof, a source portion, a drain portion, and a gate portion, the method including: growing monocrystalline doped silicon in a gate channel provided under the gate portion, and also growing amorphous doped silicon, by supplying at least silicon-containing gas and doping gas; and monocrystallizing the amorphous doped silicon by using the monocrystalline doped silicon as a seed by heating the amorphous doped silicon and the monocrystalline doped silicon.

Furthermore, according to an aspect of the present invention, there is provided a substrate processing apparatus including: a substrate having an insulating film in at least a portion of a surface thereof, a source portion, a drain portion, and a gate portion; a process chamber configured to process the substrate; a heating mechanism configured to heat an inside of the process chamber; a gas supply unit configured to supply at least silicon-containing gas and doping gas to the process chamber; and a control unit configured to control at least the heating mechanism and the gas supply unit, wherein the control unit controls the gas supply unit and the heating mechanism such that the silicon-containing gas and the doping gas are supplied to grow monocrystalline doped silicon in a gate channel provided under the gate portion, and also grow amorphous doped silicon, and the amorphous doped silicon is then monocrystallized by heating the amorphous doped silicon and the monocrystalline doped silicon.

According to an embodiment of the present invention, it is possible to provide a method for processing a substrate, a method for manufacturing a semiconductor device, and a substrate processing apparatus, which can form a source/drain region with a desired dopant concentration while ensuring a deposition rate.

### BRIEF DESCRIPTION OF THE DRAWINGS

FIG. 1 is a perspective view of a substrate processing apparatus applied to the present invention;

FIG. 2 is a schematic configuration view around a process furnace of a substrate processing apparatus applied to the present invention;

FIG. 3 is a flow illustrating the case of performing a substrate processing process in the present invention by using an in-situ process;

FIGS. 4A to 4C are schematic views illustrating a solid phase epitaxial growth method;

FIGS. 5A to 5D are process views illustrating a monocrystalline SiCP film deposition process in a first embodiment of the present invention;

FIGS. 6A to 6D are process views illustrating a monocrystalline SiCP film deposition process in a second embodiment of the present invention; and

FIG. 7 is a flow illustrating the case of performing a substrate processing process in the present invention by using an ex-situ process.

### DETAILED DESCRIPTION

Hereinafter, embodiments of the present invention will be described with reference to the attached drawings. In the following embodiments, in an apparatus using a solid phase epitaxial growth method which is an example of a substrate processing apparatus, so-called batch-type vertical apparatuses in which wafers are arranged in a vertical direction will be described. Note that the use of the batch-type vertical apparatus increases the number of wafers that can be processed at once, thus improving the throughput.

### First Embodiment

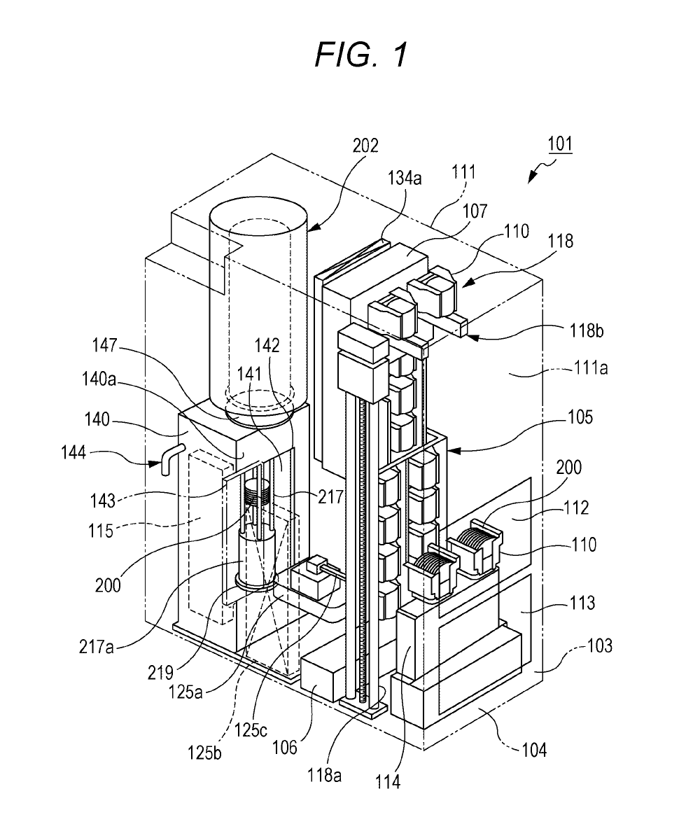

FIG. 1 is a perspective view of a substrate processing apparatus applied to the present invention.

As illustrated in FIG. 1, a substrate processing apparatus 101 according to an embodiment of the present invention uses cassettes (FOUP, also referred to as “pods”) 110 as wafer carriers to accommodate substrates (also referred to as “wafers”) 200 formed of a material such as silicon, and the substrate processing apparatus 101 includes a housing 111. At the lower side of a front wall 111a of the housing 111, a front maintenance port 103 is provided as an opening part for enabling maintenance, and a front maintenance door 104 is installed to open and close the front maintenance port 103. At the front maintenance door 104, a cassette carrying port (substrate container carrying port) 112 is provided to connect the inside and the outside of the housing 111, and the cassette carrying port 112 is configured to be opened and closed by a front shutter (substrate container carrying port opening/closing mechanism) 113. A cassette stage (substrate container stage) 114 is installed inside the cassette carrying port 112 of the housing 111. The cassette 110 is carried onto the cassette stage 114 and carried away from the cassette stage 114 by an in-process carrying device (not illustrated). The cassette stage 114 is configured such that the cassette 110 is placed on the cassette stage 114 by the in-process carrying device in such a manner that the wafers 200 are vertically positioned in the cassette 110 and a wafer port of the cassette 110 faces upward.

A cassette shelf (substrate container shelf) 105 is installed near a central lower part inside the housing 111 in a front-back direction. The cassette shelf 105 is disposed to store a plurality of cassettes 110 in multiple rows and columns in such a manner that the wafers 200 can be carried into and out of the cassettes 110. The cassette shelf 105 is installed to be horizontally movable on a slide stage (horizontal movement mechanism) 106.

Also, a buffer shelf (substrate container storage shelf) 107 is installed at the upper side of the cassette shelf 105 to store the cassettes 110.

A cassette carrying device (substrate container carrying device) 118 is installed between the cassette stage 114 and the cassette shelf 105. The cassette carrying device 118 includes a cassette elevator (substrate container lift mechanism) 118a capable of holding and lifting the cassettes 110, and a cassette carrying mechanism (substrate container carrying mechanism) 118b as a carrying mechanism. The cassette carrying device 118 is configured such that the cassettes 110 are carried among the cassette stage 114, the cassette shelf 105 and the buffer shelf 107 by consecutive operations of the cassette elevator 118a and the cassette carrying mechanism 118b.

A wafer transfer mechanism (substrate transfer mechanism) 125 is installed at the rear side of the cassette shelf 105. The wafer transfer mechanism 125 includes a wafer transfer device (substrate transfer device) 125a capable of rotating or linearly moving the wafer 200 in a horizontal direction, and a wafer transfer device elevator (substrate transfer device lift mechanism) 125b configured to lift and lower the wafer transfer device 125a.

As schematically illustrated in FIG. 1, the wafer transfer device elevator 125b is installed at the left end part of a pressure-resistant housing 140. By consecutively operating the wafer transfer device elevator 125b and the wafer transfer device 125a and using a tweezer (substrate holder) 125c of the wafer transfer device 125a as a placement part of the wafer 200, the wafer 200 is loaded (charged) into and unloaded (discharged) from a boat (substrate holder) 217 having an insulating part 217a.

As illustrated in FIG. 1, a cleaning unit 134a including a supply fan and a dust filter is provided at the rear side of the buffer shelf 107 to supply clean air as a cleaned atmosphere, so that clean air is circulated in the housing 111. Also, at the right-end part opposite to the wafer transfer device elevator 125b, another cleaning unit (not illustrated) including a supply fan and a dust filter is installed to supply clean air. Clean air blown by this cleaning unit flows through the wafer transfer device 125a and is then sucked by an exhaust device (not illustrated) and the air is exhausted to the outside of the housing 111.

A housing (hereinafter referred to as “pressure-resistant housing”) 140, which is airtight and can be kept at a pressure lower than an atmospheric pressure (hereinafter referred to as “negative pressure”), is installed at the rear side of the wafer transfer device (substrate transfer device) 125a. The pressure-resistant housing 140 forms a loadlock chamber 141 that is a loadlock-type standby chamber having a sufficient volume for accommodating the boat 217. A wafer carrying port (substrate carrying port) 142 is provided at a front wall 140a of the pressure-resistant housing 140. The wafer carrying port 142 is configured to be opened and closed by a gate valve (substrate carrying port opening/closing mechanism) 143. A gas supply pipe 144 configured to supply inert gas such as nitrogen gas to the loadlock chamber 141 and a gas exhaust pipe (not illustrated) configured to exhaust the loadlock chamber 141 to a negative pressure are respectively connected to a pair of sidewalls of the pressure-resistant housing 140.

A process furnace 202 is installed at the upper side of the loadlock chamber 141. The bottom side of the process furnace 202 is configured to be opened and closed by a furnace port gate valve (furnace port opening/closing mechanism) 147. As schematically illustrated in FIG. 1, a boat elevator (substrate holder lift mechanism) 115 is installed in the loadlock chamber 141 to lift and lower the boat 217. A seal cap 219 is horizontally installed as a cover at an arm (not illustrated) connected to the boat elevator 115 as a connector. The seal cap 219 is configured to support the boat 217 vertically and close the bottom side of the process furnace 202.

The boat 217 includes a plurality of holding members and is configured to hold a plurality of (for example, about 50 to 150) wafers 200 horizontally in a state where the wafers 200 are vertically stacked with their centers aligned.

Next, an operation of the substrate processing apparatus 101 according to an embodiment of the present invention will be described.

As illustrated in FIG. 1, before the cassette 110 is supplied to the cassette stage 114, the cassette carrying port 112 is opened by the front shutter 113. Thereafter, the cassette 110 is carried through the cassette carrying port 112 and placed on the cassette stage 114 in such a manner that the wafers 200 are vertically positioned in the cassette 110 and a wafer port of the cassette 110 faces upward.

Next, by the cassette carrying device 118, the cassette 110 is picked up from the cassette stage 114 and is vertically rotated by 90° clockwise to the rear side of the housing 111, so that the wafers 200 inside the cassette 110 are horizontally positioned and the wafer port of the cassette 110 faces the rear side of the housing 111.

Subsequently, the cassette 110 is automatically carried to a predetermined shelf position of the cassette shelf 105 or the buffer shelf 107 by the cassette carrying device 118, and after the cassette 110 is temporarily stored, the cassette 110 is transferred to the cassette shelf 105 by the cassette carrying device 118. Alternatively, the cassette 110 is directly carried to the cassette shelf 105 by the cassette carrying device 118.

The slide stage 106 moves the cassette shelf 105 horizontally so as to place the cassette 110 to be transferred at a position facing the wafer transfer device 125a.

When the wafer carrying port 142 of the loadlock chamber 141 kept at the atmospheric pressure is opened by the operation of the gate valve 143, a wafer 200 is picked up from the cassette 110 through the wafer port of the cassette 110 by the tweezer 125c of the wafer transfer device 125a, is carried into the loadlock chamber 141 through the wafer carrying port 142 and is transferred and charged into the boat 217 (wafer charging). After transferring the wafer 200 to the boat 217, the wafer transfer device 125a returns to the cassette 110 and charges the next wafer 200 into the boat 217.

When a predetermined number of wafers 200 are charged into the boat 217, the wafer carrying port 142 is closed by the gate valve 143, and the loadlock chamber 141 is depressurized by evacuation through an exhaust pipe. When the inside pressure of the loadlock chamber 141 becomes equal to the inside pressure of the process furnace 202, the bottom side of the process furnace 202 is opened by the furnace port gate valve 147. Subsequently, the seal cap 219 is lifted up by the boat elevator 115, so that the boat 217 supported by the seal cap 219 is carried (loaded) into the process furnace 202.

After the loading of the boat 217, a predetermined process is performed on the wafers 200 in the process furnace 202.

After the process, the boat 217 is taken out by the boat elevator 115, the inside pressure of the loadlock chamber 141 is adjusted back to the atmospheric pressure, and then the gate valve 143 is opened. Thereafter, in the reverse order, the wafers 200 and the cassette 110 are discharged to the outside of the housing 111.

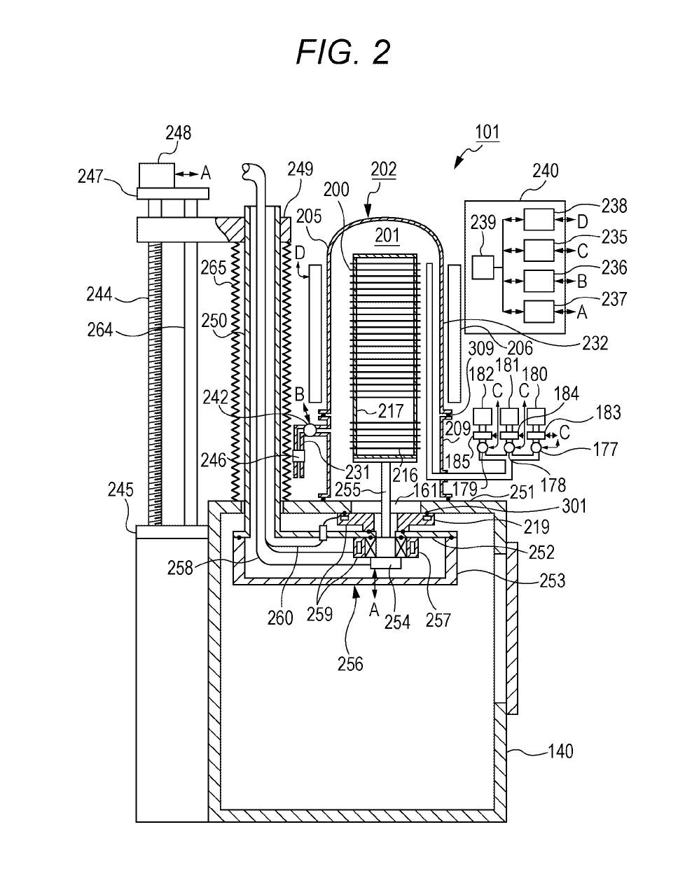

FIG. 2 is a schematic configuration view, illustrated as a vertical cross-sectional view, of the process furnace 202 and therearound of the substrate processing apparatus 101.

As illustrated in FIG. 2, the process furnace 202 includes a heater 206 as a heating mechanism.

The heater 206 has a cylindrical shape and includes a heating wire and an insulating member provided around the heating wire. The heater 206 is vertically installed by being supported by a holder (not illustrated).

Inside the heater 206, an outer tube 205 used as a reaction tube is installed concentrically with the heater 206. The outer tube 205 is formed of a heat-resistant material such as quartz (SiO₂) or silicon carbide (SiC), and has a cylindrical shape with a closed top side and an opened bottom side. In the hollow cylindrical portion inside the outer tube 205, a process chamber 201 is formed to accommodate the boat 217 in which the wafers 200 as substrates are horizontally positioned and vertically stacked in multiple stages.

At the bottom side of the outer tube 205, a manifold 209 is installed concentrically with the outer tube 205. For example, the manifold 209 is formed of stainless steel and has a cylindrical shape with opened top and bottom sides. The manifold 209 is provided to support the outer tube 205. Also, an O-ring 309 is provided as a seal member between the manifold 209 and the outer tube 205. The manifold 209 is supported by a holder (not illustrated) such that the outer tube 205 is kept in an upright position. In this manner, a reaction container is formed by the outer tube 205 and the manifold 209.

A gas exhaust pipe 231 is provided at the manifold 209, and a gas supply pipe 232 is provided through the manifold 209. The upstream side of the gas supply pipe 232 is divided into three branches, and the three branches are respectively connected to first to third gas supply sources 180, 181 and 182 through valves 177, 178 and 179 and mass flow controllers (MFCs) 183, 184 and 185 that are used as gas flow control devices. A gas flow control unit 235 is electrically connected to the MFCs 183, 184 and 185 and the valves 177, 178 and 179 to perform control such that a desired amount of gas is supplied at a desired timing.

A vacuum exhaust device 246 such as a vacuum pump is connected to the downstream side of the gas exhaust pipe 231 through a pressure sensor (not illustrated) used as a pressure detector and an automatic pressure controller (APC) valve 242 used as a pressure regulator.

A pressure control unit 236 is electrically connected to the pressure sensor and the APC valve 242. By adjusting the opening degree of the APC valve 242 based on a pressure detected by the pressure sensor, the pressure control unit 236 performs control such that the inside pressure of the process chamber 201 is adjusted to a desired pressure at a desired timing.

Under the manifold 209, the seal cap 219 is provided as a lid member of a furnace port for airtightly sealing the opened bottom side of the manifold 209. For example, the seal cap 219 is formed of a metal such as stainless steel and has a disk shape. An O-ring 301 is provided on the top of the seal cap 219 as a seal member that is in contact with the bottom side of the manifold 209.

A rotary mechanism 254 is provided at the seal cap 219.

A rotation shaft 255 of the rotary mechanism 254 is connected to the boat 217 through the seal cap 219 to rotate the wafers 200 by rotating the boat 217.

The seal cap 219 is configured to be moved vertically by a lift motor 248 (which will be described later) provided as a lift mechanism outside the process furnace 202, so that the boat 217 can be loaded into and unloaded from the process chamber 201.

A driving control unit 237 is electrically connected to the rotary mechanism 254 and the lift motor 248 to control a desired operation at a desired timing.

Near the heater 206, a temperature sensor (not illustrated) is provided as a temperature detector to detect the inside temperature of the process chamber 201.

A temperature control unit 238 is electrically connected to the heater 206 and the temperature sensor. By adjusting the conduction condition of the heater 206 based on temperature information detected by the temperature sensor, the temperature control unit 238 performs control such that the inside temperature of the process chamber 201 is adjusted to a desired temperature distribution at a desired timing.

In the configuration of the process furnace 202, first process gas is supplied from the first gas supply source 180, and the flow rate of the first process gas is adjusted by the MFC 183. Thereafter, the first process gas is supplied into the process chamber 201 by the gas supply pipe 232 through the valve 177.

Also, second process gas is supplied from the second gas supply source 181, and the flow rate of the second process gas is adjusted by the MFC 184. Thereafter, the second process gas is supplied into the process chamber 201 by the gas supply pipe 232 through the valve 178.

Third process gas is supplied from the third gas supply source 182, and the flow rate of the third process gas is adjusted by the MFC 185. Thereafter, the third process gas is supplied into the process chamber 201 by the gas supply pipe 232 through the valve 179. Also, the process gas in the process chamber 201 is exhausted therefrom by the vacuum pump as the vacuum exhaust device 246 connected to the gas exhaust pipe 231.

Next, the configuration around the process furnace 202 of the substrate processing apparatus 101 used in the present invention will be described in detail.

A lower base 245 is provided on the outer side of the loadlock chamber 141 used as a preliminary chamber.

A guide shaft 264 fitted to a lift plate 249 and a ball screw 244 screwed to the lift plate 249 are installed at the lower base 245. An upper base 247 is installed on the upper ends of the guide shaft 264 and the ball screw 244 erected on the lower base 245.

The ball screw 244 is rotated by the lift motor 248 installed on the upper base 247. The lift plate 249 is configured to be lifted and lowered by the rotation of the ball screw 244.

A hollow lift shaft 250 is vertically installed at the lift plate 249, and a connection portion between the lift plate 249 and the lift shaft 250 is airtightly sealed. The lift shaft 250 is configured to be lifted and lowered together with the lift plate 249. The lift shaft 250 is movably inserted through a top plate 251 of the loadlock chamber 141. A through hole of the top plate 251 through which the lift shaft 250 is inserted is large enough to prevent the lift shaft 250 from contacting the top plate 251.

Between the loadlock chamber 141 and the lift plate 249, a bellows 265 is installed as a flexible hollow structure to cover the periphery of the lift shaft 250 in order to airtightly seal the loadlock chamber 141.

The bellows 265 can be sufficiently expanded and contracted in accordance with the lift amount of the lift plate 249, and the bellows 265 has an inner diameter sufficiently greater than the outer shape of the lift shaft 250 so as not to make contact with the lift shaft 250 during expansion or contraction.

A lift base 252 is horizontally fixed to the lower end of the lift shaft 250. A drive part cover 253 is airtightly attached to the bottom of the lift base 252 through a seal member such as an O-ring. The lift base 252 and the drive part cover 253 form a drive part accommodating case 256. With this configuration, the inside of the drive part accommodating case 256 is isolated from the inside atmosphere of the loadlock chamber 141.

Also, the rotary mechanism 254 for the boat 217 is installed inside the drive part accommodating case 256, and the surroundings of the rotary mechanism 254 are cooled by a cooling mechanism 257.

A power supply cable 258 is connected from the upper end of the lift shaft 250 to the rotary mechanism 254 through a hollow portion of the lift shaft 250. Also, a cooling passage 259 is formed in the cooling mechanism 257 and the seal cap 219, and a coolant tube 260 is connected from the upper end of the lift shaft 250 to the cooling passage 259 through the hollow portion of the lift shaft 250 to supply cooling water.

As the ball screw 244 is rotated by the operation of the lift motor 248, the drive part accommodating case 256 is lifted and lowered through the lift plate 249 and the lift shaft 250.

As the drive part accommodating case 256 is lifted, a furnace port 161 that is an opening part of the process furnace 202 is closed by the seal cap 219 airtightly installed at the lift base 252, and in this state, wafer processing is possible. By lowering the drive part accommodating case 256, both the seal cap 219 and the boat 217 can be lowered to carry the substrates 200 to the outside.

The gas flow rate control unit 235, the pressure control unit 236, the driving control unit 237, and the temperature control unit 238 constitute an operation unit and an input/output unit, and they are electrically connected to a main control unit 239 that controls the overall operation of the substrate processing apparatus 101. The gas flow rate control unit 235, the pressure control unit 236, the driving control unit 237, the temperature control unit 238, and the main control unit 239 constitute a controller 240.

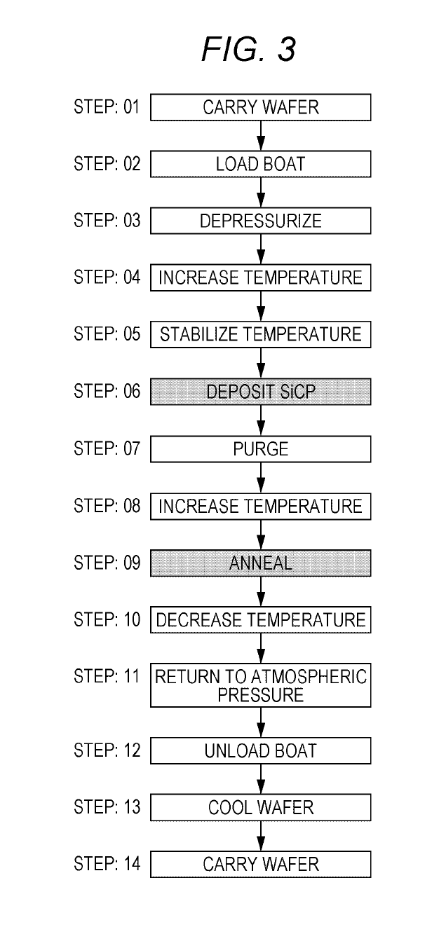

Next, as one process of a semiconductor device manufacturing process, a method for depositing a film on a substrate such as the wafer 200 by using the process furnace 202 according to the above configuration will be described with reference to FIG. 3.

Also, in the following description, the operations of the respective parts of the substrate processing apparatus 101 are controlled by the controller 240.

FIG. 3 is a flow illustrating the case of performing a substrate processing process in the present invention by using an in-situ process.

When a plurality of wafers 200 is loaded onto the boat 217 (STEP 01), the boat 217 holding the plurality of wafers 200 is loaded into the process chamber 201 by the lift operation of the lift plate 249 and the lift shaft 250 by the lift motor 248 as illustrated in FIG. 2 (boat loading) (STEP 02). In this state, the seal cap 219 seals the bottom side of the manifold 209 through the O-ring.

The inside of the process chamber 201 is vacuum-exhausted to a desired pressure (vacuum degree) by the vacuum exhaust device 246 (STEP 03). In this case, the inside pressure of the process chamber 201 is measured by the pressure sensor, and the APC valve 242 as a pressure regulator is feedback-controlled based on the measured pressure. Also, the inside of the process chamber 201 is heated to a desired temperature by the heater 206 (STEP 04). In this case, the conduction condition to the heater 206 is feedback-controlled based on temperature information detected by the temperature sensor so that the inside temperature of the process chamber 201 is adjusted to a desired temperature distribution (STEP 05). Subsequently, as the boat 217 is rotated by the rotary mechanism 254, the wafer 200 is rotated.

For example, as process gases, Si-containing gas such as SiH₄ or Si₂H₆, C-containing gas such as CH₃SiH₃, and P-containing gas such as PH₃ are respectively enclosed in the first gas supply source 180, the second gas supply source 181, and the third gas supply source 182, and subsequently, the respective process gases are supplied from these gas supply sources. After the opening degrees of the MFCs 183, 184 and 185 are adjusted to provide a desired flow rate, the valves 176, 177 and 178 are opened, the respective process gases are circulated through the gas supply pipe 232 and are supplied from the top of the process chamber 201 into the process chamber 201. The supplied gas passes through the inside of the process chamber 201 and is exhausted from the gas exhaust pipe 231.

The process gas contacts the wafer 200 while passing through the inside of the process chamber 201, and a P doped SiC (SiCP) film is deposited on the surface of the wafer 200 (STEP 06).

A gas supply port of the gas supply pipe 232 is opened in a vertically downward direction from the position near the top of the process chamber 201 to the bottom of the process chamber 201. Also, the leading end of the gas supply pipe 232 may be closed, and a plurality of gas supply ports may be provided at a sidewall portion of the gas supply pipe 232 so that the respective process gases are supplied between the wafers 200 adjacent in the vertical direction. Also, in this case, the opening area or the opening diameter of the gas supply pipe 232 may be adjusted based on the pressure loss of the gas supply pipe 232 so that the flow rates of the process gases supplied from the respective gas supply ports to between the wafer 200 are equal to each other. In addition, the gas supply pipe 232 may be provided at the bottom side of the process chamber to supply gas from the bottom side of the process chamber to the top side thereof.

After the deposition of the SiCP film, the inside atmosphere of the process chamber is purged by a predetermined purge gas (for example, H₂ gas) (STEP 07), and the temperature is increased to a predetermined heat treatment temperature (STEP 08).

When the temperature is increased to the predetermined heat treatment temperature, a heat treatment (annealing) is performed for a predetermined time (STEP 09), and an amorphous SiCP film is monocrystallized. After the lapse of the predetermined heat treatment time, an amorphous SiCP film that has not been monocrystallized in the heat treatment is etched. Thereafter, the inside temperature of the process chamber is decreased (STEP 10), and the inside pressure of the process chamber is returned to the atmospheric pressure (STEP 11).

When the inside pressure of the process chamber is returned to the atmospheric pressure, the boat holding the plurality of wafers 200 is carried to the outside of the process chamber (boat unloading) (STEP 12). When the boat is carried to the outside of the process chamber, the wafer 200 is cooled to a temperature capable of accommodation into the cassette 110 that is an accommodation container (STEP 13), and the wafer is carried to the cassette 110 (STEP 14).

Next, a substrate processing process performed in the substrate processing apparatus by using lateral solid phase epitaxial growth will be described.

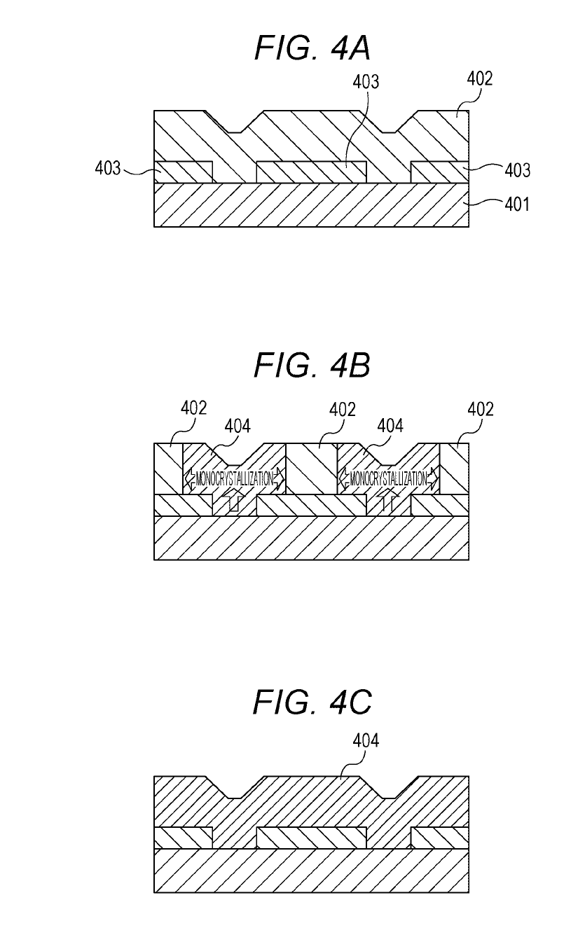

FIG. 4 is a schematic view illustrating a solid phase epitaxial growth (SPE) method.

First, as illustrated in FIG. 4A, an amorphous silicon (a-Si) film 402 is formed on an Si substrate 401 where an insulating film 403 is partially formed.

Next, the Si substrate 401 is subjected to heat treatment. Specifically, the Si substrate 401 is heated to about 500° C. to about 700° C. By subjecting the Si substrate 401 to the heat treatment, as illustrated in FIG. 4B, the a-Si film 402 on the insulating film 403 is monocrystallized using an Si opening part as a seed. By continuing the heat treatment for a predetermined time, all of the a-Si films 402 on the insulating film 403 can be monocrystallized to deposit monocrystalline Si 404 as illustrated in FIG. 4C.

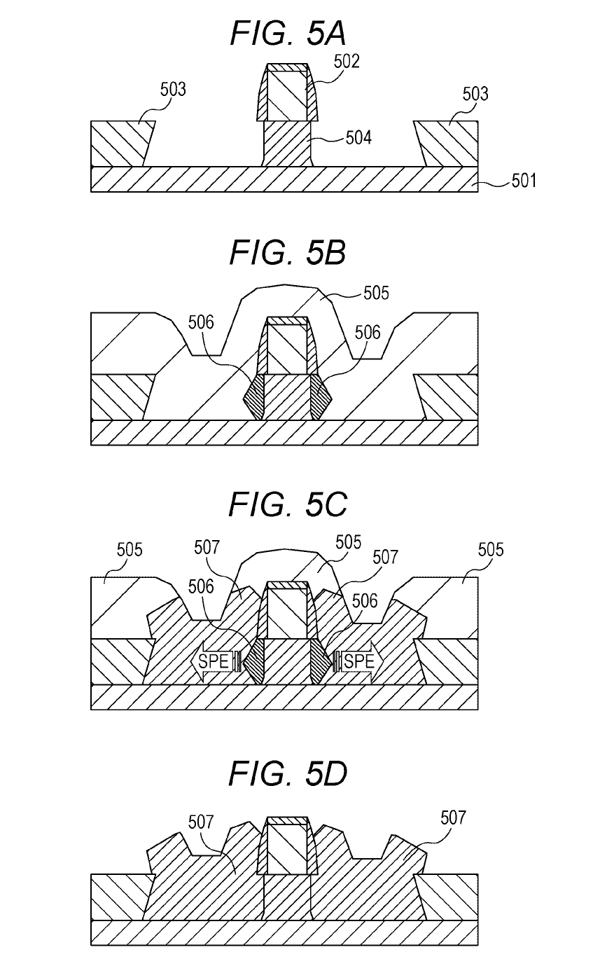

Next, a method for depositing a monocrystalline SiCP (Epitaxial-P doped SiC) film to a source/drain portion in this embodiment will be described with reference to FIGS. 5A to 5D.

FIGS. 5A to 5D are process views illustrating a monocrystalline SiCP film deposition process in the first embodiment of the present invention, and specifically process views illustrating a substrate processing process applied (STEP 06 to STEP 09).

First, as illustrated in FIG. 5A, a MOS transistor is formed on a silicon-on-insulator (SOI) substrate including a BOX layer 501. The MOS transistor is configured such that the source/drain portion is dug by etching to expose the BOX layer 501 at the bottom of the source/drain portion. Also, monocrystalline Si 504 acting as a channel of a gate portion provided at the bottom of an insulator cap 502 is configured such that at least a sidewall exposes the Si.

Next, by the substrate processing apparatus 101, silicon-containing gas such as SiH₄, carbon-containing gas such as CH₃SiH₃, and phosphorus-containing gas as doping gas such as PH₃ are supplied at a temperature range of 450° C. to 600° C. with a pressure range of 1 Pa to 1000 Pa, for example, at a process temperature of 530° C. with a pressure of 90 Pa at a SiH₄ supply flow rate of 2000 sccm and at a 1% PH₃ flow rate of 100 sccm, and film deposition is performed. Accordingly, as illustrated in FIG. 5B, an amorphous-P doped SiC (SiCP) film 505 is grown on an oxide film (a BOX layer 501 and a shallow trench isolation (STI) layer 503 of an SOI wafer), and monocrystalline SiCP 506 is grown at a sidewall portion of an Si film 504 of a gate channel (STEP 06).

Also, the deposition rate of the monocrystalline SiCP is slowed down by a high P concentration. However, since the growth rate of the amorphous SiCP is not slowed down, thick deposition can be performed with a desired P concentration.

For example, when the present invention is not used, that is, when an Epi-Si film is deposited with a desired P concentration, the deposition is performed with a DR of 1 Å/min. However, when the present invention is used, a deposition rate of about 15 Å/min to about 20 Å/min can be maintained.

Next, by performing a heat treatment (annealing) at a temperature range of 500° C. to 700° C., for example, at a process temperature of 550° C. for a predetermined time, as illustrated in FIG. 5C, the monocrystalline SiCP 506 grown at the sidewall portion of the Si film 504 in FIG. 5B acts as a seed, the amorphous SiCP 505 is monocrystallized, and a monocrystalline SiCP film 507 is grown (STEP 09).

At this time, when the heat treatment is performed at a process temperature higher than the above-described temperature range, the amorphous SiCP is polycrystallized and monocrystalline SiCP cannot be obtained. Therefore, it is important to perform SPE and perform the heat treatment at a low temperature range, at which monocrystalline SiCP is generated, without polycrystallizing the amorphous SiCP.

After the process of FIG. 5C, by etching a non-monocrystallized amorphous SiCP film 505 as illustrated in FIG. 5D, an SiCP epitaxial film 507 can be deposited with a desired P concentration maintained at the source/drain portion.

In this case, it may be preferable that the deposition be performed such that the P doping concentration in the SiC film of the source/drain portion becomes 1×10²⁰ atoms/cm³ to 1×10²¹ atoms/cm³.

Herein, in the first embodiment, for simplicity of description, STEP 06 to STEP 09 have been described as the substrate processing process; however, the present invention is not limited thereto. It is needless to say that STEP 3 to STEP 11 may be performed as the substrate processing process.

As described above, according to the first embodiment, an SiCP epitaxial film with a desired P concentration can be deposited in the source/drain portion at a predetermined rate, thereby making it possible to improve the throughput. Also, since a tensile stress is applied to the gate channel, the electron mobility in nMOS can be increased and the nMOS can be improved.

### Second Embodiment

Next, a second embodiment of the present invention will be described.

The second embodiment is different from the first embodiment in that not an SOI substrate but an Si substrate is processed and an amorphous SiCP film is deposited by forming an oxide film at a bottom portion formed by digging a source/drain portion of the Si substrate.

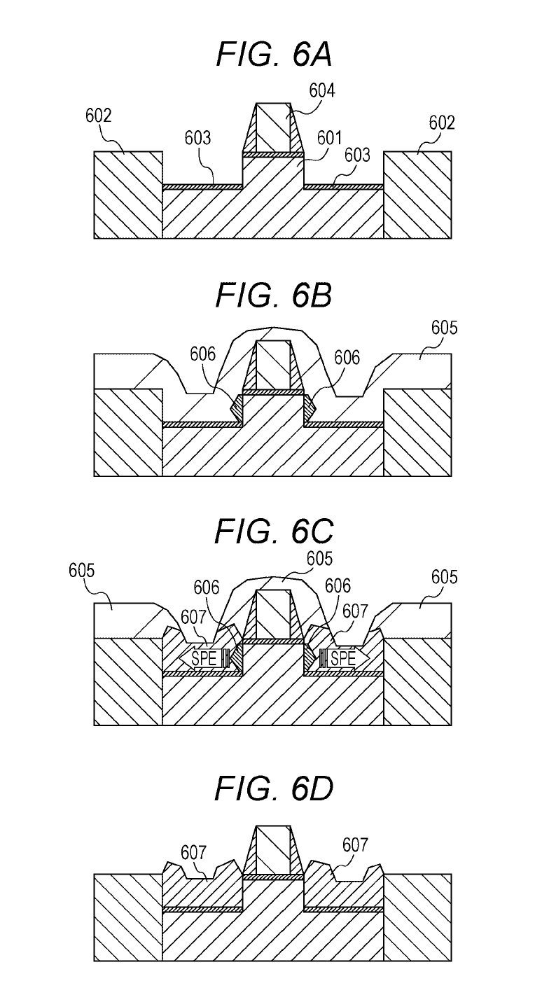

FIGS. 6A to 6D are process views illustrating a monocrystalline SiCP film deposition process in the second embodiment of the present invention.

A MOS transistor to be processed includes a shallow trench isolation (STI) film 602 that is an insulating film, and has a structure in which a source/drain portion of an Si substrate 601 is dug, an oxide film 603 (for example, SiO₂) is formed at the bottom of the source/drain portion, and monocrystalline Si is exposed at the sidewalls of a monocrystalline Si portion 601 that is a gate channel portion provided under an insulator cap 604.

In the state having the structure of FIG. 6A, substrate processing is performed through the same process as in the first embodiment.

That is, by the substrate processing apparatus 101, silicon-containing gas such as SiH₄, carbon-containing gas such as CH₃SiH₃, and phosphorus-containing gas as doping gas such as PH₃ are supplied at a temperature range of 450° C. to 600° C. with a pressure range of 1 Pa to 1000 Pa, for example, at a process temperature of 530° C. with a pressure of 90 Pa at a SiH₄ supply flow rate of 2000 sccm and at a 1% PH₃ flow rate of 100 sccm, and film deposition is performed. Accordingly, an amorphous-P doped SiC (SiCP) film is grown on an oxide film, and monocrystalline SiCP 606 is grown at a sidewall portion of an Si film 601 of a gate channel.

Next, by performing a heat treatment (annealing) at a temperature range of 500° C. to 700° C., for example, at a process temperature of 550° C. for a predetermined time, as illustrated in FIG. 6C, the monocrystalline SiCP 606 grown at the sidewall portion of the Si film 601 in FIG. 6B acts as a seed, amorphous SiCP 605 is monocrystallized, and a monocrystalline SiCP film 607 is grown.

At this time, when the heat treatment is performed at a process temperature higher than the above-described temperature range, the amorphous SiCP is polycrystallized and monocrystalline SiCP cannot be obtained. Therefore, it is important to perform SPE and perform the heat treatment at a low temperature range, at which monocrystalline SiCP is generated, without polycrystallizing the amorphous SiCP.

After the process of FIG. 6C, by etching a non-monocrystallized amorphous SiCP film 605 as illustrated in FIG. 6D, an SiCP epitaxial film 607 can be deposited with a desired P concentration maintained at the source/drain portion.

In this case, it may be preferable that the deposition be performed such that the P doping concentration in the SiC film of the source/drain portion becomes 1×10²⁰ atoms/cm³ to 1×10²¹ atoms/cm³.

As described above, according to the second embodiment, in addition to the effects obtained by the first embodiment, an Epi-SiCP film can be efficiently deposited not only in an SOI substrate but also in a general Si substrate.

### Third Embodiment

Next, a third embodiment will be described.

The third embodiment is different from the first embodiment in that substrate processing is performed by ex-situ annealing when a deposition process and a heat treatment process (annealing process) are performed in different apparatuses.

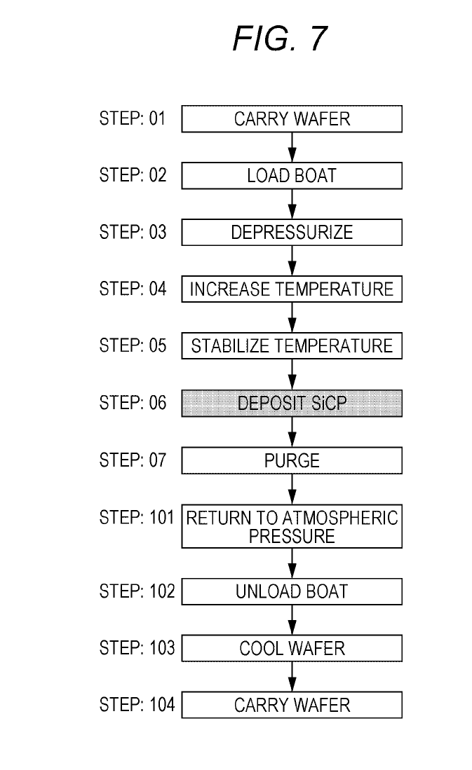

FIG. 7 is a flow illustrating the case of performing a substrate processing process in the present invention by using an ex-situ process.

In this embodiment, since the same process as in the above-described first and second embodiments is performed up to the purging of the process chamber that is STEP 07, a detailed description thereof will be omitted.

After the inside atmosphere of the process chamber is purged in STEP 07, the inside pressure of the process chamber is returned to the atmospheric pressure (STEP 101). When the inside pressure of the process chamber is returned to the atmospheric pressure, the boat is carried out (boat unloading) (STEP 102), and the wafer 200 is cooled to a predetermined temperature (STEP 103). Thereafter, when the wafer 200 is sufficiently cooled, the wafer 200 is carried (STEP 104).

As described above, according to the third embodiment, in addition to the effects obtained by the first or second embodiment, by using an ex-situ process, the deposition process and the heat treatment process can be performed by different apparatuses, and the deposition processing throughput can be improved.

Although the present invention has been described with reference to the drawings, various modifications can be made without departing from the gist of the present invention.

For example, although an insulator cap is provided at a monocrystalline Si portion of a gate channel portion in the first and second embodiments, a deposition process may be performed by exposing Si at the monocrystalline Si surface of the gate channel portion without providing the insulator cap.

Also, although three types of gases are mixed and supplied to the process chamber through one gas supply pipe in the embodiment of the present invention described above, the present invention is not limited thereto. For example, a plurality of gas supply pipes may be provided, and the gases may be mixed after being supplied to the inside of the process chamber through independent gas supply pipes provided for the respective types of gases.

In addition, although a vertical batch-type substrate processing apparatus is used in the embodiment of the present invention described above, the present invention is not limited thereto. For example, the present invention may be applied to a single-wafer type substrate processing apparatus under specific conditions.

In addition, although phosphorus (P) is used as a dopant to deposit doped silicon containing conductive impurities in the embodiment of the present invention described above, the present invention is not limited thereto. For example, impurities may be doped by using arsenic (As) or antimony (Sb) as a dopant and using gas containing these elements as doping gas.

While the present invention has been described according to the embodiments, main aspects of the present invention will be supplementarily noted hereinafter.

(Supplementary Note 1)

A method for processing a substrate by processing a substrate having an insulating film in at least a portion of a surface thereof, a source portion, a drain portion, and a gate portion, the method for processing a substrate including:
growing monocrystalline doped silicon in a gate channel provided at the gate portion, and also growing amorphous doped silicon, by supplying at least silicon-containing gas and doping gas; and
monocrystallizing the amorphous doped silicon by using the monocrystalline doped silicon as a seed by heating the amorphous doped silicon and the monocrystalline doped silicon.

(Supplementary Note 2)

The method for processing a substrate according to Supplementary Note 1, wherein monocrystalline silicon is exposed at a sidewall portion of the gate channel, and the monocrystalline doped silicon is deposited at the exposed portion.

(Supplementary Note 3)

The method for processing a substrate according to Supplementary Note 1 or 2, wherein the monocrystallizing of the amorphous doped silicon is performed at a temperature range of 400° C. to 700° C.

(Supplementary Note 4)

The method for processing a substrate according to Supplementary Notes 1 to 3, wherein an oxide film is deposited at bottom portions of the source portion and the drain portion, and the monocrystalline silicon is exposed at the sidewall portion of the gate channel.

(Supplementary Note 5)

The method for processing a substrate according to Supplementary Notes 1 to 4, wherein the monocrystallizing is preformed by solid phase epitaxial growth.

(Supplementary Note 6)

A method for manufacturing a semiconductor device by processing a substrate having an insulating film in at least a portion of a surface thereof, a source portion, a drain portion, and a gate portion, the method including:

growing monocrystalline doped silicon in a gate channel provided under the gate portion, and also growing amorphous doped silicon, by supplying at least silicon-containing gas and doping gas; and

monocrystallizing the amorphous doped silicon by using the monocrystalline doped silicon as a seed by heating the amorphous doped silicon and the monocrystalline doped silicon.

(Supplementary Note 7)

A substrate processing apparatus, including:

a substrate having an insulating film in at least a portion of a surface thereof, a source portion, a drain portion, and a gate portion;

a process chamber configured to process the substrate;

a gas supply unit configured to supply at least silicon-containing gas and doping gas to the process chamber; and

a control unit configured to control at least the gas supply unit,

wherein the control unit controls the gas supply unit such that the silicon-containing gas and the doping gas are supplied to grow monocrystalline doped silicon in a gate channel provided at the gate portion, and also grow amorphous doped silicon.

(Supplementary Note 8)

The substrate processing apparatus according to Supplementary Note 7, further including a heating mechanism configured to heat an inside of the process chamber,
wherein the control unit controls the heating mechanism such that the amorphous doped silicon is monocrystallized by heating the amorphous doped silicon and the monocrystalline doped silicon after growing the amorphous doped silicon and the monocrystalline doped silicon.

1. A method for processing a substrate having an insulating film in at least a portion of a surface thereof, a source portion, a drain portion, and a gate portion, the method for processing a substrate comprising:
growing monocrystalline doped silicon in a gate channel provided at the gate portion, and also growing amorphous doped silicon, by supplying at least silicon-containing gas and doping gas; and
monocrystallizing the amorphous doped silicon by using the monocrystalline doped silicon as a seed by heating the amorphous doped silicon and the monocrystalline doped silicon.

2. The method for processing a substrate according to claim 1, wherein monocrystalline silicon is exposed at a sidewall portion of the gate channel, and the monocrystalline doped silicon is deposited at the exposed portion.

3. The method for processing a substrate according to claim 1, wherein the monocrystallizing of the amorphous doped silicon is performed at a temperature range of 400 C to 700 C.

4. The method for processing a substrate according to claim 1, wherein an oxide film is deposited at bottom portions of the source portion and the drain portion, and the monocrystalline silicon is exposed at the sidewall portion of the gate channel.

5. The method for processing a substrate according to claim 1, wherein the monocrystallizing is preformed by solid phase epitaxial growth.

6. A method for manufacturing a semiconductor device by processing a substrate having an insulating film in at least a portion of a surface thereof, a source portion, a drain portion, and a gate portion, the method comprising:
growing monocrystalline doped silicon in a gate channel provided at the gate portion, and also growing amorphous doped silicon, by supplying at least silicon-containing gas and doping gas; and
monocrystallizing the amorphous doped silicon by using the monocrystalline doped silicon as a seed by heating the amorphous doped silicon and the monocrystalline doped silicon.

7. A substrate processing apparatus, comprising:
a substrate having an insulating film in at least a portion of a surface thereof, a source portion, a drain portion, and a gate portion;
a process chamber configured to process the substrate;
a gas supply unit configured to supply at least silicon-containing gas and doping gas to the process chamber; and
a control unit configured to control at least the gas supply unit,
wherein the control unit controls the gas supply unit such that the silicon-containing gas and the doping gas are supplied to grow monocrystalline doped silicon in a gate channel provided at the gate portion, and also grow amorphous doped silicon.

8. The substrate processing apparatus according to claim 7, further comprising a heating mechanism configured to heat an inside of the process chamber,
wherein the control unit controls the heating mechanism such that the amorphous doped silicon is monocrystallized by heating the amorphous doped silicon and the monocrystalline doped silicon after growing the amorphous doped silicon and the monocrystalline doped silicon.
